(19) United States
(12) Patent Application Publication
(10) Pub. No.: US 2023/0320056 A1
(43) Pub. Date: Oct. 5, 2023

(54) NANOSHEET PULL-UP TRANSISTOR IN SRAM

(71) Applicant: INTERNATIONAL BUSINESS MACHINES CORPORATION, ARMONK, NY (US)

(72) Inventors: HUIMEI ZHOU, Albany, NY (US); Carl Radens, LaGrangeville, NY (US); MIAOMIAO WANG, Albany, NY (US); Ardasheir Rahman, Schenectady, NY (US)

(21) Appl. No.: 17/657,961

(22) Filed: Apr. 5, 2022

(51) Int. Cl. H01L 27/11; G11C 11/412; H01L 29/06; H01L 21/8238

(52) U.S. Cl. CPC H01L 27/1104; G11C 11/412; H01L 29/0665; H01L 21/823807

(57) ABSTRACT

Embodiments of present invention provide a static random-access-memory (SRAM) device. The SRAM device includes a first set of nanosheets used in an n-type transistor; and a second set of nanosheets with one or more nanosheets of the second set of nanosheets used in a p-type transistor, wherein a width of the second set of nanosheets is wider than a width of the first set of nanosheets. In one embodiment the p-type transistor is used as a pull-up transistor and the n-type transistor is used as a pull-down transistor or a pass-gate transistor. A method of manufacturing the SRAM device is also provided.

### FIELD OF THE INVENTION

The present application relates to manufacturing of semiconductor integrated circuits. More particularly, it relates to nanosheet pull-up transistors used in a SRAM memory device and method of manufacturing the same.

### BACKGROUND

Static random-access-memory (SRAM) has been widely used in semiconductor devices and circuitries. When designing and manufacturing SRAM memories, factors that are critical to the performance of SRAM memory includes, for example, write-read-margin (WRM) and bias temperature instability (BTI) or normalized BTI (NBTI). Generally, in order to increase write-read-margin, pull-up (PU) transistors are made to have relatively small or weak current, in the overall design of the SRAM configuration and/or in comparison with that of pull-down (PD) transistors and pass-gate (PG) transistors. For example, in SRAM memory that uses fin-type field-effect-transistors (finFETs), making small and weak current for PU transistors leads to using smaller number of fins for PU transistors. Similarly, when applying nanosheet transistor technology in designing SRAM memory, making small and weak current for PU transistors means using nanosheets with narrow sheet width for PU transistors. While write-read-margin (WRM) may be improved by using nanosheets with narrow sheet width for PU transistors, there is still the concern as to how to improve bias temperature instability of SRAM memories that are based on nanosheet technology due to tradeoff between sheet width and NBTI.

### SUMMARY

Embodiments of present invention provide a transistor circuitry such as a SRAM memory device. The transistor circuitry includes a first set of nanosheets used in an n-type transistor; and a second set of nanosheets with one or more nanosheets of the second set of nanosheets used in a p-type transistor, wherein a width of the second set of nanosheets is wider than a width of the first set of nanosheets.

According to one embodiment, the one or more nanosheets is a first sub-set of the second set of nanosheets and the second set of nanosheets further includes a second sub-set. The p-type transistor has source/drain regions formed at two ends of the first sub-set of the second set of nanosheets, and two ends of the second sub-set of the second set of nanosheets are isolated from the source/drain regions of the p-type transistor. In one embodiment, the first sub-set of the second set of nanosheets is positioned above the second sub-set of the second set of nanosheets.

According to another embodiment, the first set of nanosheets and the second set of nanosheets have a same number of nanosheets, and wherein the p-type transistor is a pull-up transistor, and the n-type transistor is either a pull-down transistor or a pass-gate transistor.

According to one embodiment, the one or more nanosheets has a same number of nanosheets as that of the first set of nanosheets. According to another embodiment, the first set of nanosheets and the second set of nanosheets are vertically stacked together.

Embodiments of present invention further provide a method of manufacturing the above transistor circuitry such as a SRAM memory device.

### BRIEF DESCRIPTION OF THE DRAWINGS

The present invention will be understood and appreciated more fully from the following detailed description of embodiments of present invention, taken in conjunction with accompanying drawings of which:

FIGS. 1A, 1B, 1C, and 1D are demonstrative illustrations of various cross-sectional views of a semiconductor structure during a process of manufacturing a SRAM memory according to embodiments of a method of present invention;

FIGS. 2A, 2B, 2C, and 2D are demonstrative illustrations of various cross-sectional views of a semiconductor structure, following a step illustrated in FIGS. 1A, 1B, 1C, and 1D, during a process of manufacturing a SRAM memory according to embodiments of a method of present invention;

FIGS. 3A, 3B, 3C, and 3D are demonstrative illustrations of various cross-sectional views of a semiconductor structure, following a step illustrated in FIGS. 2A, 2B, 2C, and 2D, during a process of manufacturing a SRAM memory according to embodiments of a method of present invention;

FIGS. 4A, 4B, 4C, and 4D are demonstrative illustrations of various cross-sectional views of a semiconductor structure, following a step illustrated in FIGS. 3A, 3B, 3C, and 3D, during a process of manufacturing a SRAM memory according to embodiments of a method of present invention;

FIGS. 5A, 5B, 5C, and 5D are demonstrative illustrations of various cross-sectional views of a semiconductor structure, following a step illustrated in FIGS. 4A, 4B, 4C, and 4D, during a process of manufacturing a SRAM memory according to embodiments of a method of present invention;

FIGS. 6A, 6B, 6C, and 6D are demonstrative illustrations of various cross-sectional views of a semiconductor structure, following a step illustrated in FIGS. 5A, 5B, 5C, and 5D, during a process of manufacturing a SRAM memory according to embodiments of a method of present invention;

FIGS. 7A, 7B, 7C, and 7D are demonstrative illustrations of various cross-sectional views of a semiconductor structure, following a step illustrated in FIGS. 6A, 6B, 6C, and 6D, during a process of manufacturing a SRAM memory according to embodiments of a method of present invention;

FIGS. 8A, 8B, 8C, and 8D are demonstrative illustrations of various cross-sectional views of a semiconductor structure, following a step illustrated in FIGS. 7A, 7B, 7C, and 7D, during a process of manufacturing a SRAM memory according to embodiments of a method of present invention;

FIGS. 9A, 9B, 9C, and 9D are demonstrative illustrations of various cross-sectional views of a semiconductor structure during a process of manufacturing a SRAM memory according to additional embodiments of a method of present invention;

FIGS. 10A, 10B, 10C, and 10D are demonstrative illustrations of various cross-sectional views of a semiconductor structure, following a step illustrated in FIGS. 9A, 9B, 9C, and 9D and other steps similar to those illustrated in FIGS. 2A-7D, during a process of manufacturing a SRAM memory according to embodiments of a method of present invention; and

FIG. 11 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity or they are embodied in a single physical entity.

### DETAILED DESCRIPTION OF PREFERRED EMBODIMENTS

In the below detailed description and the accompanying drawings, it is to be understood that various layers, structures, and regions shown in the drawings are both demonstrative and schematic illustrations that are not drawn to scale. In addition, for the ease of explanation, one or more layers, structures, and regions of a type commonly used to form semiconductor devices or structures may not be explicitly shown in a given drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the drawings to denote the same or similar features, elements, or structures, and thus, a detailed explanation of the same or similar features, elements, or structures may not be repeated for each of the drawings. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

To provide spatial context to the different structural orientations of the semiconductor structures shown throughout the drawings, XYZ Cartesian coordinates may be shown in each of the drawings. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

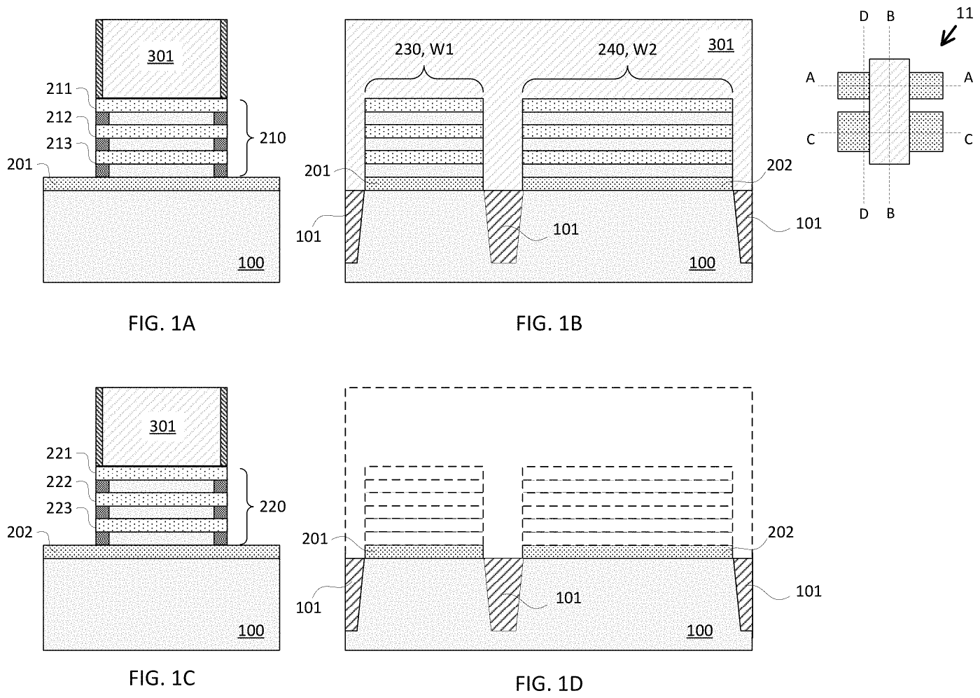

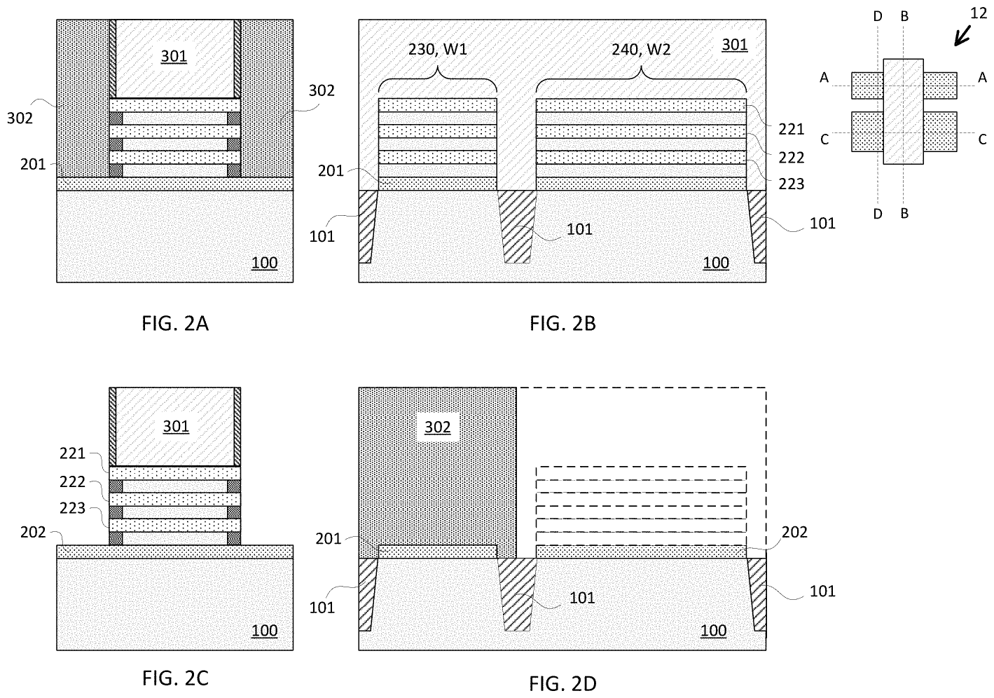

FIGS. 1A, 1B, 1C, and 1D are demonstrative illustrations of various cross-sectional views of a semiconductor structure 11 during a process of manufacturing a transistor circuitry such as a SRAM memory according to embodiments of present invention. More specifically, referring to a simplified top view of layout of the semiconductor structure 11 shown at the upper-right corner, FIG. 1A and FIG. 1C illustrate cross-sectional views of the semiconductor structure 11 along the A-A dash line and the C-C dash line perpendicularly across gate respectively; FIG. 1B illustrates a cross-sectional view of the semiconductor structure 11 along the B-B dash line perpendicularly across nanosheets; and FIG. 1D illustrates a cross-sectional view of the semiconductor structure 11 along the D-D dash line perpendicularly across source/drain regions. The D-D dash line parallels to the B—B dash line. In the following drawings from FIGS. 2A-2D to FIGS. 10A-10D, cross-sectional reviews of the semiconductor structure at various manufacturing stages are also provided in a similar manner as to FIGS. 1A-1D. Denotations of these drawings are similar to the above and will not be repeated.

For example, FIG. 1A illustrates a cross-sectional view of the semiconductor structure 11 perpendicularly across a gate of an n-type transistor and FIG. 1C illustrates a cross-sectional view of the semiconductor structure 11 perpendicularly across a gate of a p-type transistor. According to one embodiment of present invention and as described hereinafter, n-type transistors are used as pass-gate (PG) transistors and pull-down (PD) transistors in the static random-access-memory (SRAM) and p-type transistors are used as pull-up (PU) transistors of the SRAM. FIG. 1B illustrates a cross-sectional view of the semiconductor structure 11 across nanosheets along a direction of gate width of the n-type transistor and p-type transistor.

More particularly, an n-type transistor 230 includes a first set of nanosheets that has a first width W1 and a p-type transistor 240 includes a second set of nanosheets that has a second width W2. First width W1 is a channel width of the n-type transistor 230 and second width W2 is a channel width of the p-type transistor 240. According to one embodiment of present invention, the channel width of the p-type transistor 240, i.e., second width W2, is larger than the channel width of the n-type transistor 230, i.e., first width W1. According to one embodiment of present invention, a p-type transistor made from the second set of nanosheets with a wider channel width W2 may have improved bias temperature instability (BTI).

In order to strike a balance between BTI and write-read-margin (WRM), according to one embodiment of present invention, the use of wider channel width W2 for p-type transistor may be partially compensated by using a fewer number of nanosheets for the p-type transistor such that the current of p-type transistor may be weakened or reduced. Using a fewer number of nanosheets may be achieved, in one embodiment, by removing or etching away some nanosheets from the second set of nanosheets of second width W2 through additional patterning and etching processes. Alternatively, some of the nanosheets in the second set of nanosheets may be blocked by dielectric material and thereby prevented source/drain being formed at the ends thereof, resulting less or fewer number of nanosheets, with second width W2, being used in forming p-type transistor as being described below in more details. Additionally, in order to reduce or weaken current of the p-type transistor, the second set of nanosheets (for p-type transistor) may be extremely less doped, not doped at all, or even doped with anti-dopants. Doping the second set of nanosheets may be performed at one or more stages of manufacturing of the SRAM device.

More specifically, one embodiment of present invention includes providing a semiconductor substrate 100 and forming a first set of nanosheets 210 and a second set of nanosheets 220 on top thereof. The semiconductor substrate 100 may be, for example, a bulk silicon (Si) substrate, a bulk germanium (Ge) substrate, a SiGe substrate, or a silicon-on-insulator (SOI) substrate. However, embodiments of present invention are not limited in this aspect and other types of substrates may be used as well. Hereinafter, for the ease of description without loss of generality, the semiconductor substrate 100 may be described as a silicon (Si) substrate. The semiconductor substrate 100 may have one or more shallow trench isolations (STIs) 101 formed therein.

The first set of nanosheets 210 and the second set of nanosheets 220 may be formed on a same plane, as being demonstratively illustrated hereinafter, and may be formed to be parallel or side-to-side to each other and separated by an STI 101 in the semiconductor substrate 100. However, embodiments of present invention are not limited in this aspect. For example, the first set of nanosheets 210 and the second set of nanosheets 220 may be formed in a stacked fashion. In other words, the first set of nanosheets 210 may be formed on top of, or underneath, the second set of nanosheets 220 and separated by a dielectric layer vertically. Moreover, the first set of nanosheets 210 and the second set of nanosheets 220 may be formed in any other positional relationship. Description hereinafter will focus mainly on the first and second sets of nanosheets 210 and 220 that are formed in a same plane parallel to each other, as being illustrated in most of the drawings. However, a person skilled in the art will appreciate that similar description may be applied to the first and second sets of nanosheets 210 and 220 that, for example, are formed in a stacked fashion or in any other positional relationship. In all the embodiments, the first set of nanosheets 210 has a first width W1 and the second set of nanosheets 220 has a width W2, and W2 is larger than W1.

The first set of nanosheets 210 may include, for example, nanosheets 211, 212, and 213 although more or fewer number of nanosheets are possible and are fully contemplated herein. The second set of nanosheets 220 may include, for example, nanosheets 221, 222, and 223 although more or fewer number of nanosheets are possible and are fully contemplated herein. In one embodiment, the first set of nanosheets 210 may have a same number of nanosheets as that of the second set of nanosheets 220. The first set of nanosheets 210 may be formed on top of a dielectric layer 201, such as silicon-nitride (SiN), above the semiconductor substrate 100, and the second set of nanosheets 220 may be formed on top of a dielectric layer 202, such as SiN, above the semiconductor substrate 100 as well. The first set of nanosheets 210 and the second set of nanosheets 220 may be covered by a dummy gate 301 such as a polysilicon dummy gate. In one embodiment, the dummy gate 301 may fill in a gap, which sits directly above the STI 101, between the first set of nanosheets 210 and the second set of nanosheets 220.

FIGS. 2A, 2B, 2C, and 2D are demonstrative illustrations of various cross-sectional views of a semiconductor structure 12, following a step illustrated in FIGS. 1A, 1B, 1C, and 1D, during a process of manufacturing a transistor circuitry such as a SRAM memory according to embodiments of a method of present invention. More particularly, embodiments of present invention provide forming source/drain regions of the n-type transistor 230 using the first set of nanosheets 210 and forming source/drain regions of the p-type transistor 240 using the second set of nanosheets 220. Source/drain regions of the n-type transistor 230 may be formed first, or alternatively source/drain regions of the p-type transistor 240 may be formed first. In the below description, for the sake of explanation, source/drain regions of the p-type transistor 240 are described as being formed first, followed by the formation of source/drain regions of the n-type transistor 230. However, a person skilled in the art will appreciate that a similar process may be used to form source/drain regions of the n-type transistor 230 first followed by the formation of source/drain regions of the p-type transistor 240.

Specifically, embodiments of present invention provide forming a hard mask 302 covering the two ends of the first set of nanosheets 210. In other words, embodiments of present invention provide forming the hard mask 302 to protect areas of the first set of nanosheets 210 where source/drain regions of the n-type transistor 230 may be formed before proceeding to form source/drain regions of the p-type transistor 240 as being described below in more details.

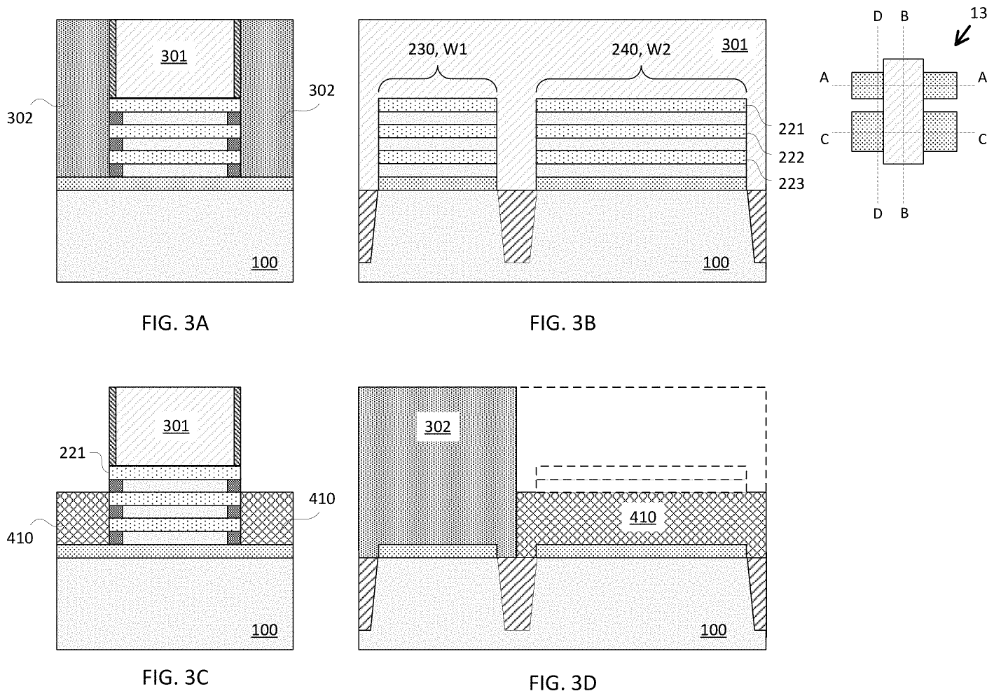

FIGS. 3A, 3B, 3C, and 3D are demonstrative illustrations of various cross-sectional views of a semiconductor structure 13, following a step illustrated in FIGS. 2A, 2B, 2C, and 2D, during a process of manufacturing a transistor circuitry such as a SRAM memory according to embodiments of a method of present invention. More particularly, after covering the first set of nanosheets 210, embodiments of present invention provide forming a dielectric layer 410 to cover the two ends of one or more nanosheets of the second set of nanosheets 220. For example, the two ends of the nanosheets 222 and 223 of the second set of nanosheets 220 may be covered by the dielectric layer 410, leaving only the two ends of the nanosheet 221 exposed. In doing so, embodiments of present invention may include forming a dielectric layer, such as a silicon-oxide (SiO₂) and through for example a deposition process, to cover sidewall surfaces of the two ends of all the nanosheets of the second set of nanosheets 220, and subsequently recessing the dielectric layer down to expose one or more nanosheets of the second set of nanosheets 220. By exposing only one or more nanosheets, instead of all the nanosheets, of the second set of nanosheets 220, embodiments of present invention enable forming the p-type transistor 240 with fewer number of nanosheets as compared to forming the n-type transistor 230 with all the nanosheets in the first set of nanosheets 210 as being described below in more details.

According to embodiments of present invention, using fewer number of nanosheets in forming the p-type transistor 240 helps, at least partially, weakening the current of the p-type transistor 240. By weakening the current of the p-type transistor 240, the write-read-margin of a SRAM memory, which uses p-type transistors as pull-up transistors, may be improved. In the meantime, the wider channel width of the p-type transistor 240, by using the second set of nanosheets 220 with wider width W2, helps improve the bias temperature instability (BTI) of the p-type transistor 240.

Using a fewer number of nanosheets, by selectively leaving some nanosheets out that are otherwise available for forming the p-type transistor as being described above, partially compensates for the use of wider width nanosheets in the p-type transistor 240. Moreover, reducing the number of sheets used for the p-type transistor may also be achieved by forming a fewer number of nanosheets for the p-type transistor at the beginning, as compared with that for the n-type transistor. For example, instead of forming the first set of nanosheets 210 to have the same number of nanosheets as that of the second set of nanosheets 220, the second set of nanosheets 220 may be formed to have a fewer number of nanosheets. Other ways to achieve having different numbers of nanosheets for p-type transistor and n-type transistor may include, for example, removing or etching away some nanosheets for the p-type transistor at different stages of the SRAM manufacturing process with additional patterning.

In weakening the current of the p-type transistor 240, embodiments of present invention are not limited in the above aspect. For example, embodiments of present invention provide method of reducing or decreasing p-type transistor current by, for example, using extremely less dopant density, as compared with dopant density normally used in p-type logic transistors, in the channel region of p-type transistor. For example, a dopant density or concentration of 10¹⁵ to 10¹⁸ atoms/cm³ or less may be used. In some other embodiment, channel region of the p-type transistor may be un-doped to contain no dopant at all. In yet another embodiment, instead of p-type dopants, n-type dopants that are normally used for n-type transistor may be used here as anti-dopant for the p-type transistor such that current of the p-type transistor may be further weakened. As is known in the art, boron (B), gallium (Ga), and indium (In) are well known p-type dopants and arsenic (As) and phosphorus (P) are well known n-type dopant. However, the dopants are not limited to the above and other types of dopants may be used as well. Additional embodiment of present invention may include, for example, reducing source/drain contact size by performing contact size modulation to the p-type transistor. Reducing the contact size to the source/drain region of the p-type transistor effectively increases contact resistance to the source/drain region which affects the current going through source/drain region of the p-type transistor.

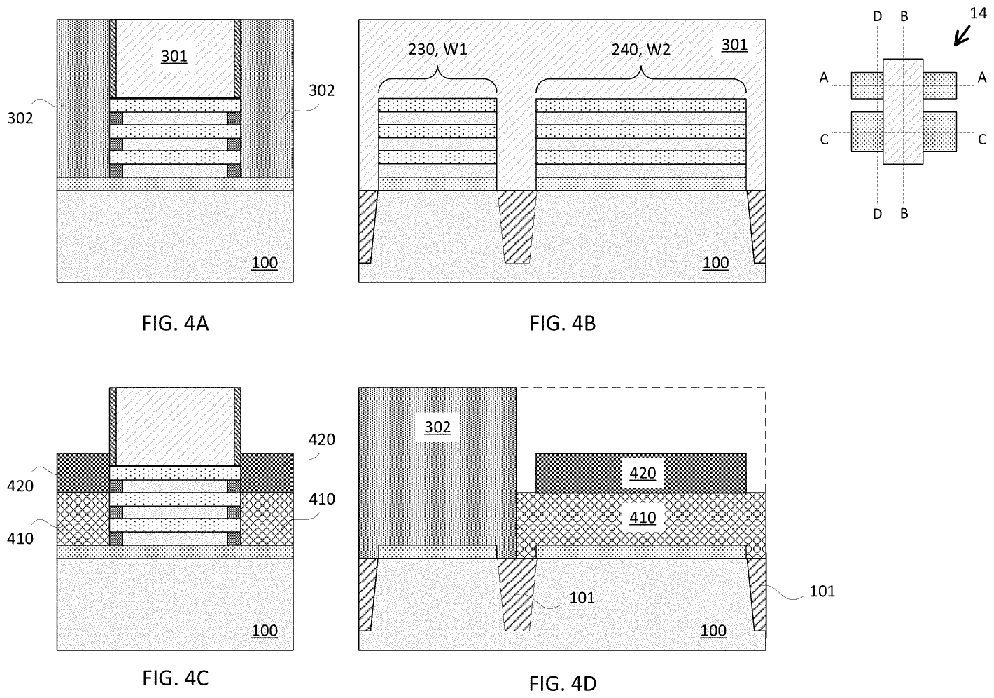

FIGS. 4A, 4B, 4C, and 4D are demonstrative illustrations of various cross-sectional views of a semiconductor structure 14, following a step illustrated in FIGS. 3A, 3B, 3C, and 3D, during a process of manufacturing a transistor circuitry such as a SRAM memory according to embodiments of a method of present invention. More particularly, embodiments of present invention provide forming source/drain regions 420 of the p-type transistor 240 through epitaxial growth at the exposed nanosheet 221 of the second set of nanosheets 220, and in particular at sidewall surfaces of the two ends of the nanosheet 221. The second set of nanosheets 220 may include a first sub-set of nanosheets including, for example, the nanosheet 221 and a second sub-set of nanosheets including, for example, the nanosheets 222 and 223. With the dummy gate 301 covering the gate region, the hard mask 302 covering the first set of nanosheets 210, and the dielectric layer 410 covering the second sub-set of the second set of nanosheets 220, the source/drain regions 420 may be formed through epitaxial growth at sidewall surfaces of the two ends of the first sub-set of the second set of nanosheets 220.

Here it is to be noted that, the first sub-set of the second set of nanosheets 220 is illustrated and described, as a non-limiting example, to include the nanosheet 221 and the second sub-set of the second set of nanosheets 220 is illustrated and described, as a non-limiting example, to include the nanosheet 222 and the nanosheet 223. The first sub-set of the second set of nanosheets 220 is illustrated and described, as a non-limiting example, to be positioned above the second sub-set of the second set of nanosheets 220. The first sub-set of the second set of nanosheets 220 forms the p-type transistor 240 that does not involve the second sub-set of the second set of nanosheets 220. In other words, the second sub-set of the second set of nanosheets 220 is not used in the p-type transistor 240 and is isolated from the source/drain regions 420 of the p-type transistor 240. A person skilled in the art will appreciate that embodiments of present invention may include various variations to the above, such as the number of nanosheets in the first sub-set and second sub-set, their positional relationship with each other, etc., all of which are fully contemplated here.

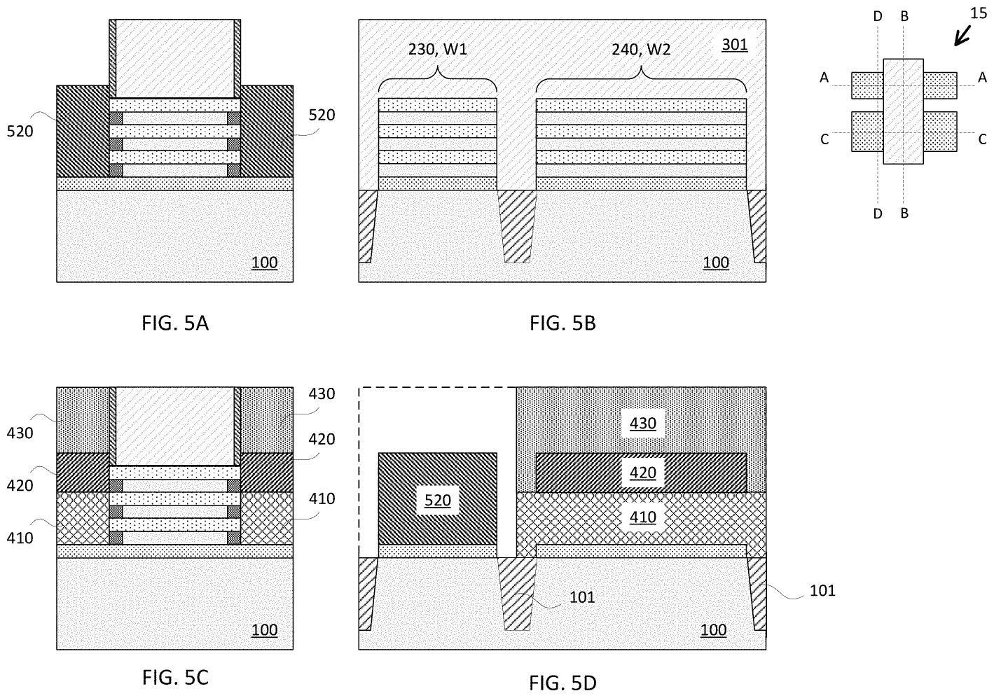

FIGS. 5A, 5B, 5C, and 5D are demonstrative illustrations of various cross-sectional views of a semiconductor structure 15, following a step illustrated in FIGS. 4A, 4B, 4C, and 4D, during a process of manufacturing a transistor circuitry such as a SRAM memory according to embodiments of a method of present invention. More particularly, after the formation of the source/drain regions 420 of the p-type transistor 240, embodiments of present invention provide forming a hard mask 430 to cover the source/drain regions 420 and removing the hard mask 302 to expose sidewall surfaces of the two ends of the first set of nanosheets 210. Subsequently, source/drain regions 520 of the n-type transistor 230 using the first set of nanosheets 210 may be formed. The formation may be through epitaxial growth at sidewall surfaces of the two ends of the first set of nanosheets 210 which includes all the nanosheets 211, 212, and 213. In other words, the n-type transistor 230 uses more number of nanosheets than the p-type transistor 240.

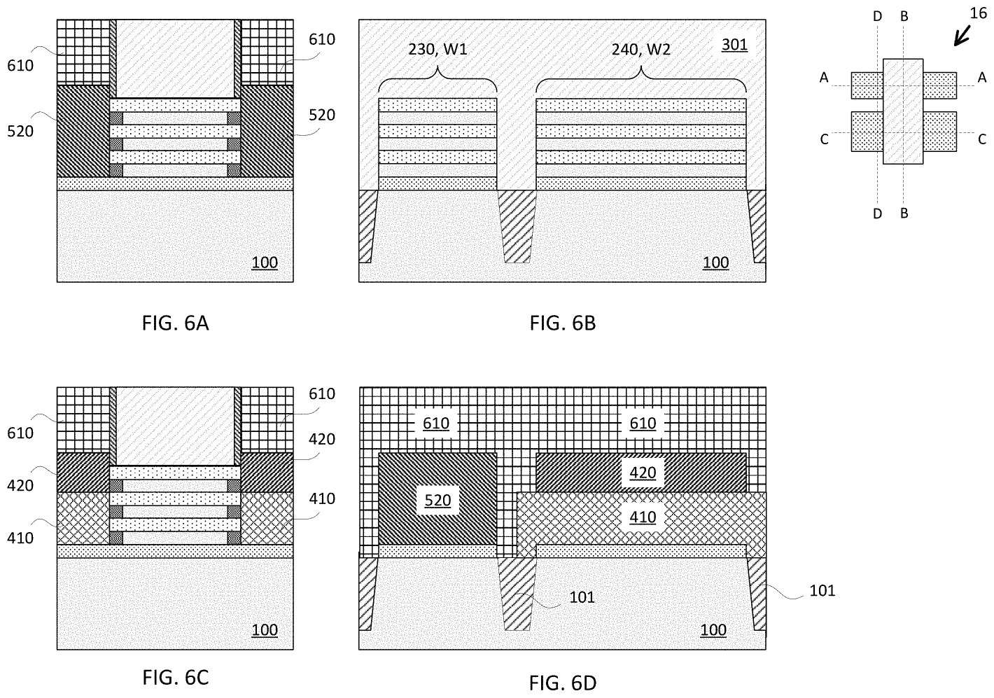

FIGS. 6A, 6B, 6C, and 6D are demonstrative illustrations of various cross-sectional views of a semiconductor structure 16, following a step illustrated in FIGS. 5A, 5B, 5C, and 5D, during a process of manufacturing a transistor circuitry such as a SRAM memory according to embodiments of a method of present invention. Following the formation of the source/drain regions 420 of the p-type transistor 240 and the source/drain regions 520 of the n-type transistor 230, embodiments of present invention provide removing the hard mask 430 and forming an inter-level-dielectric (ILD) layer 610 to cover the source/drain regions 420 and 520 of both the p-type transistor 240 and the n-type transistor 230 in preparation for forming gate metals for the transistors next.

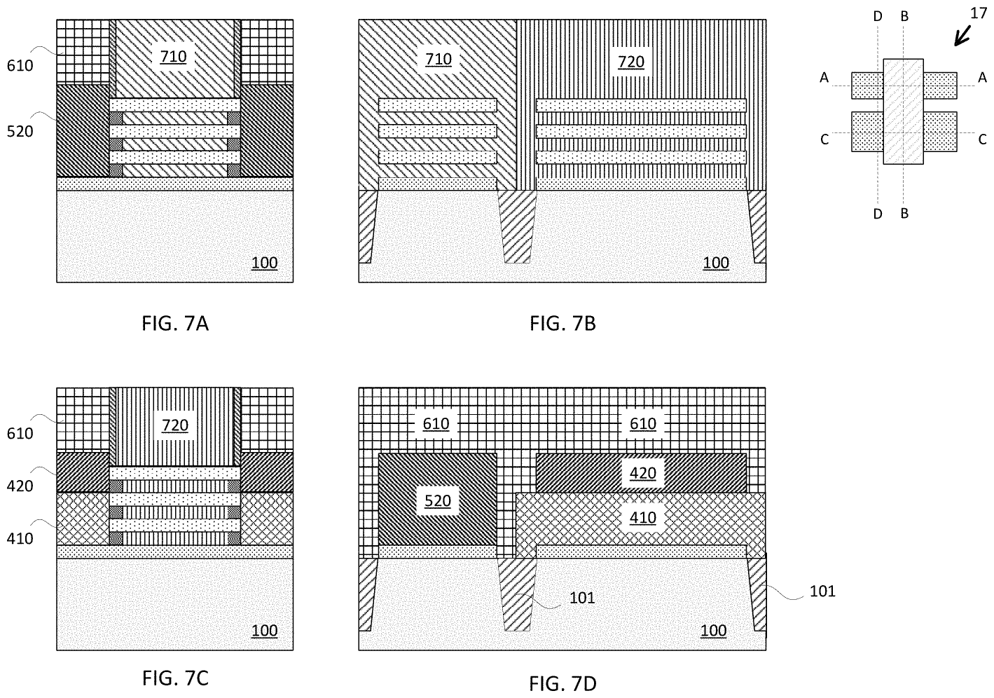

FIGS. 7A, 7B, 7C, and 7D are demonstrative illustrations of various cross-sectional views of a semiconductor structure 17, following a step illustrated in FIGS. 6A, 6B, 6C, and 6D, during a process of manufacturing a transistor circuitry such as a SRAM memory according to embodiments of a method of present invention. More specifically, a gate metal 710 for the n-type transistor 230 may be formed through a replacement-metal-gate (RMG) process to surround each individual nanosheets 211, 212, and 213 in the first set of nanosheets 210. For example, the dummy gate 301 may first be selectively removed through a selective etching process. Next, semiconductor materials surrounding the nanosheets 211, 212, and 213 may be removed as well through a selective etching process. A gate metal 710, including one or more layers of work-function metals for n-type transistors, may be deposited onto exposed surfaces of the nanosheets 211, 212, and 213. Similarly, a gate metal 720 may be formed through another RMG process to surround each individual nanosheets 221, 222, and 223 in the second set of nanosheets 220. Here it is to be noted that although source/drain regions of the p-type transistor 240 are only formed at the two ends of the nanosheet 221, the gate metal 720 may be formed to surround the nanosheets 222 and 223 as well. Nevertheless, the nanosheets 222 and 223 are inactive and the two ends of the nanosheets 222 and 223 are isolated form the source/drain regions 420 of the p-type transistor 240.

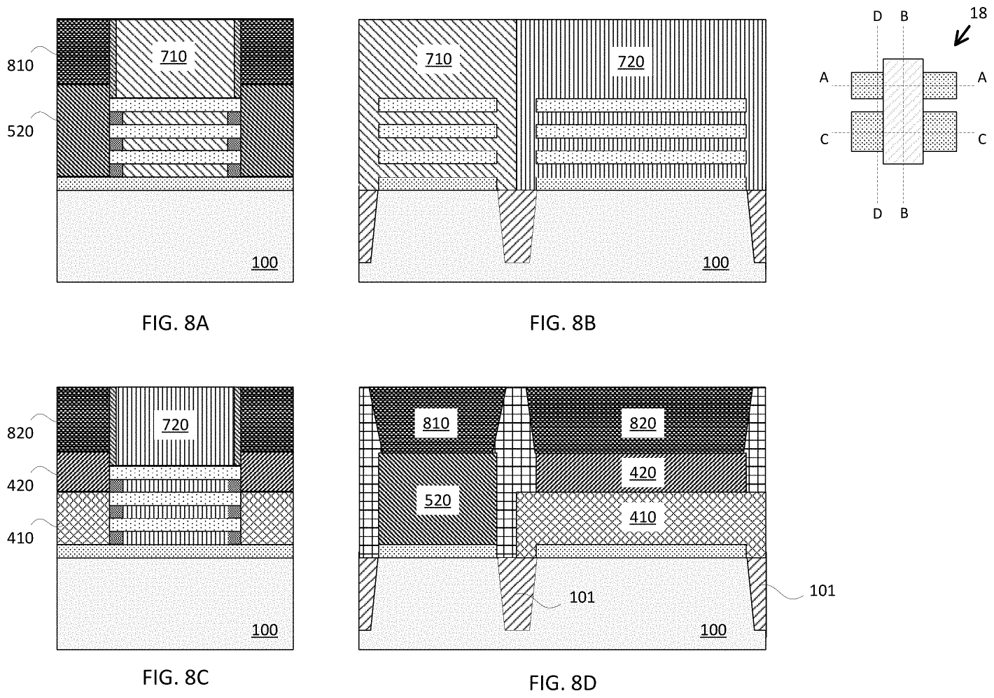

FIGS. 8A, 8B, 8C, and 8D are demonstrative illustrations of various cross-sectional views of a semiconductor structure, following a step illustrated in FIGS. 7A, 7B, 7C, and 7D, during a process of manufacturing a transistor circuitry such as a SRAM memory according to embodiments of a method of present invention. More particularly, contacts may be formed to contact the source/drain regions of the p-type transistor 240 and the n-type transistor 230. For example, a contact 810 may be formed to contact the source/drain region 520 of the n-type transistor 230 and a contact 820 may be formed to contact the source/drain region 420 of the p-type transistor 240. More particularly, contact openings in the ILD layer 610 may first be created through, for example, a lithographic patterning and etching process. The contact openings may then be filled with conductive materials such as, for example, tungsten (W), cobalt (Co), and copper (Cu) to name a few.

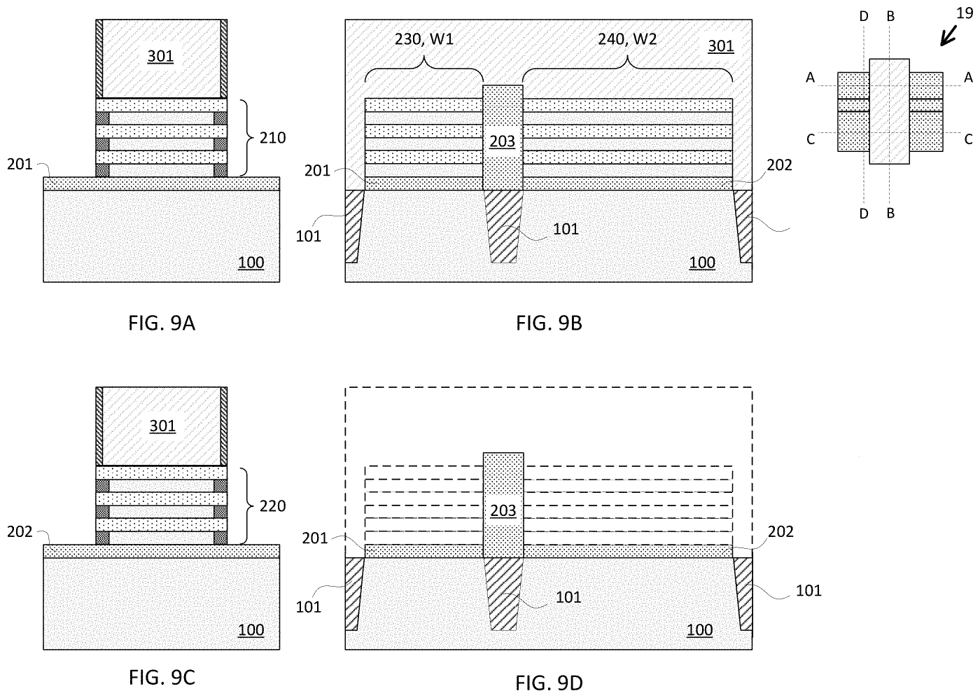

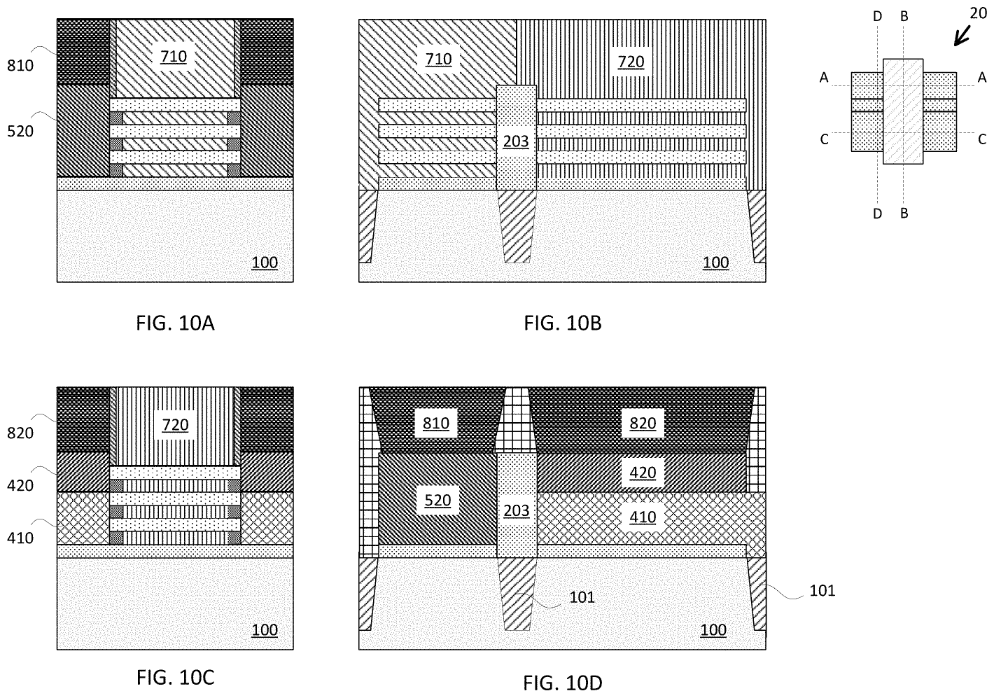

FIGS. 9A, 9B, 9C, and 9D are demonstrative illustrations of various cross-sectional views of a semiconductor structure 19 during a process of manufacturing a transistor circuitry such as a SRAM memory according to additional embodiments of a method of present invention. More specifically, different from the first set of nanosheets 210 and the second set of nanosheets 220 illustrated in FIGS. 1A-1D, in this embodiment, the first set of nanosheets 210 and the second set of nanosheets 220 are directly separated by a dielectric layer 203 in between. According to embodiments of present invention, manufacturing process steps similar to those described above may be similarly applied to form the p-type transistor 240 with a wider channel width W2 and fewer number of channels than the channel width W1 and number of channels of the n-type transistor 239. Here, the number of channels refer to the corresponding number of nanosheets used in a transistor. The resulting structure is described below in more details with reference to FIGS. 10A-10D.

FIGS. 10A, 10B, 10C, and 10D are demonstrative illustrations of various cross-sectional views of a semiconductor structure 20, following a step illustrated in FIGS. 9A, 9B, 9C, and 9D and other steps similar to those illustrated in FIGS. 2A-7D, during a process of manufacturing a transistor circuitry such as a SRAM memory according to embodiments of a method of present invention. More particularly, the p-type transistor 240 and the n-type transistor 230, as being illustrated in FIGS. 10A-10D, have similar structure and/or configuration to those being illustrated in FIGS. 8A-8D. For example, the p-type transistor 240 has a wider width W2 than that of the n-type transistor 230 which helps improve the bias temperature instability (BTI) of the p-type transistor 240. On the other hand, the p-type transistor 240 uses fewer number of nanosheets than that of the n-type transistor 230, which results in reduction in current of the p-type transistor 240, thereby at least partially compensating the increase in current due to increase in the channel width W2 of the p-type transistor 240. The reduction in current helps improve the write-read-margin (WRM) of the SRAM device.

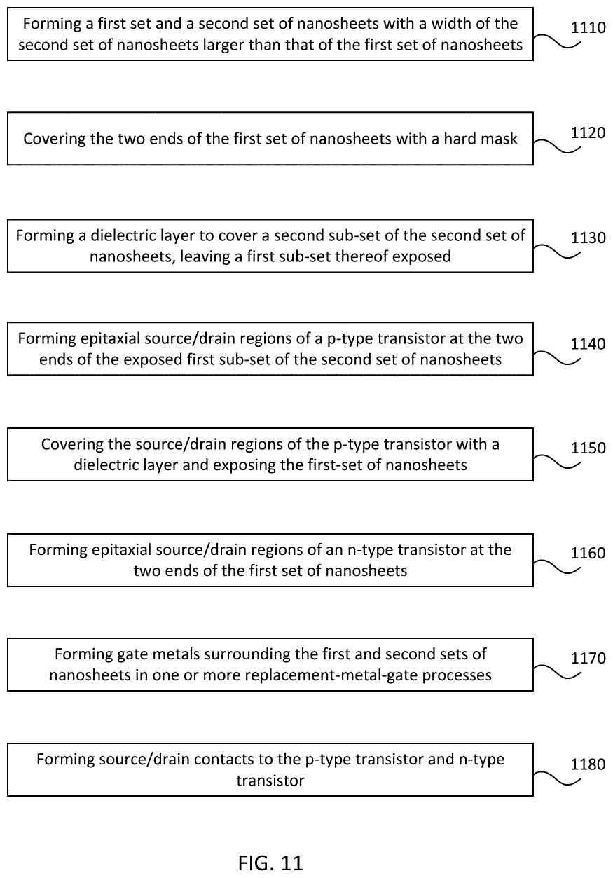

FIG. 11 is a demonstrative illustration of a flow-chart of a method of manufacturing a semiconductor structure according to embodiments of present invention. More specifically, in forming the semiconductor structure which may be a SRAM memory device or more generally a transistor circuitry, embodiments of present invention provide (1110) forming a first set and a second set of nanosheets with a width of the second set of nanosheets larger than that of the first set of nanosheets. The first set of nanosheets may be used in forming an n-type transistor and at least a first sub-set of the second set of nanosheets may be used in forming a p-type transistor. Embodiments further provide (1120) covering the two ends of the first set of nanosheets with a first hard mask in preparation for forming source/drain regions of the p-type transistor; (1130) forming a dielectric layer such as an inter-level-dielectric (ILD) layer to cover a second sub-set of the second set of nanosheets such that only the first sub-set of the second set of nanosheets is used in forming the p-type transistor; and (1140) forming epitaxial source/drain regions of the p-type transistor at the two ends of the exposed first sub-set of the second set of nanosheets. After forming the source/drain regions of the p-type transistor, embodiments further provide (1150) covering the source/drain regions of the p-type transistor with a second hard mask and removing the first hard mask to expose the first set of nanosheets for the n-type transistor; (1160) forming epitaxial source/drain regions of the n-type transistor at the two ends of the first set of nanosheets. Next, embodiments provide (1170) forming gate metals surrounding the first and second sets of nanosheets in one or more replacement-metal-gate (RMG) processes and subsequently (1180) forming contacts to contact the source/drain regions of the p-type transistor and the n-type transistor.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Although exemplary embodiments have been described herein with reference to the accompanying figures, it is to be understood that the invention is not limited to those precise embodiments, and that various other changes and modifications may be made therein by one skilled in the art without departing from the scope of the appended claims.

It is to be understood that the various layers, structures, and/or regions described above are not necessarily drawn to scale. In addition, for ease of explanation one or more layers, structures, and regions of a type commonly used to form semiconductor devices or structures may not be explicitly shown in a given illustration or drawing. This does not imply that any layers, structures, and regions not explicitly shown are omitted from the actual semiconductor structures.

Furthermore, it is to be understood that the embodiments discussed herein are not limited to the particular processing steps shown and described herein. In particular, with respect to semiconductor processing steps, it is to be emphasized that the descriptions provided herein are not intended to encompass all of the processing steps that may be used to form a functional semiconductor integrated circuit device. Rather, certain processing steps that are commonly used in forming semiconductor devices, such as, for example, wet cleaning and annealing steps, are purposefully not described herein for economy of description.

Terms such as “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Also, in the figures, the illustrated scale of one layer, structure, and/or region relative to another layer, structure, and/or region is not necessarily intended to represent actual scale.

Semiconductor devices and methods for forming same in accordance with the above-described techniques can be employed in various applications, hardware, and/or electronic systems, including but not limited to personal computers, communication networks, electronic commerce systems, portable communications devices (e.g., cell and smart phones), solid-state media storage devices, functional circuitry, etc. Given the teachings provided herein, one of ordinary skill in the art will be able to contemplate other implementations and applications of embodiments of the invention.

In some embodiments, the above-described techniques are used in connection with manufacture of semiconductor integrated circuit devices that illustratively include, by way of non-limiting example, CMOS devices, MOSFET devices, and/or FinFET devices, and/or other types of semiconductor integrated circuit devices that incorporate or otherwise utilize CMOS, MOSFET, and/or FinFET technology.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other higher level carrier) or in a multichip package (such as a ceramic carrier that has either or both surface interconnections or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While certain features of the invention have been illustrated and described herein, many modifications, substitutions, changes, and equivalents will now occur to those of ordinary skill in the art. Such changes, modification, and/or alternative embodiments may be made without departing from the spirit of present invention and are hereby all considered within the scope of present invention. It is, therefore, to be understood that the appended claims are intended to cover all such modifications and changes as fall within the spirit of the invention.

What is claimed is:

1. A transistor circuitry comprising:
a first set of nanosheets used in an n-type transistor; and
a second set of nanosheets with one or more nanosheets of the second set of nanosheets used in a p-type transistor,
wherein a width of the second set of nanosheets is wider than a width of the first set of nanosheets.

2. The transistor circuitry of claim 1, wherein the one or more nanosheets is a first sub-set of the second set of nanosheets and the second set of nanosheets further comprises a second sub-set, the p-type transistor has source/drain regions formed at two ends of the first sub-set of the second set of nanosheets, and two ends of the second sub-set of the second set of nanosheets are isolated from the source/drain regions of the p-type transistor.

3. The transistor circuitry of claim 2, wherein the first sub-set of the second set of nanosheets is positioned above the second sub-set of the second set of nanosheets.

4. The transistor circuitry of claim 1, wherein the first set of nanosheets and the second set of nanosheets have a same number of nanosheets, the p-type transistor is a pull-up transistor, and the n-type transistor is either a pull-down transistor or a pass-gate transistor.

5. The transistor circuitry of claim 1, wherein the one or more nanosheets of the second set of nanosheets have a same number of nanosheets as that of the first set of nanosheets.

6. The transistor circuitry of claim 1, wherein the width of the first set of nanosheets is a channel width of the n-type transistor and the width of the second set of nanosheets is a channel width of the p-type transistor.

7. A method of making a transistor circuitry, the method comprising:
forming a first set of nanosheets and a second set of nanosheets, wherein a width of the second set of nanosheets is wider than a width of the first set of nanosheets;
forming source/drain regions of a p-type transistor at two ends of one or more nanosheets of the second set of nanosheets; and
forming source/drain regions of an n-type transistor at two ends of the first set of nanosheets.

8. The method of claim 7, further comprising covering the two ends of the first set of nanosheets with a first hard mask before forming the source/drain regions of the p-type transistor.

9. The method of claim 8, wherein the one or more nanosheets is a first sub-set of the second set of nanosheets and the second set of nanosheets further comprises a second sub-set, and wherein forming the source/drain regions of the p-type transistor comprises forming a dielectric layer covering the second sub-set of the second set of nanosheets and forming the source/drain regions of the p-type transistor at the two ends of the first sub-set of the second set of nanosheets.

10. The method of claim 9, wherein forming the dielectric layer covering the second sub-set of the second set of nanosheets comprises depositing the dielectric layer to cover all the second set of nanosheets, and subsequently recessing the dielectric layer to expose the first sub-set of the second set of nanosheets.

11. The method of claim 10, further comprising covering the source/drain regions of the p-type transistor with a second hard mask before forming the source/drain regions of the n-type transistor.

12. The method of claim 7, further comprising forming a first gate metal surrounding the first set of nanosheets for the n-type transistor and forming a second gate metal surrounding at least the one or more nanosheets of the second set of nanosheets for the p-type transistor.

13. The method of claim 12, wherein the one or more nanosheets of the second set of nanosheets is a first sub-set of the second set of nanosheets and the second set of nanosheets further comprises a second sub-set, wherein the second gate metal further surrounds the second sub-set of the second set of nanosheets.

14. The method of claim 7, wherein the one or more nanosheets of the second set of nanosheets is doped with a p-type dopant of a density less than 10¹⁵ atoms/cm³, not doped, or doped with an n-type dopant.

15. A semiconductor structure comprising:
a first set of nanosheets used in an n-type transistor; and
a second set of nanosheets having a first sub-set and a second sub-set thereof,
wherein the first sub-set of the second set of nanosheets is used in a p-type transistor, and a width of the second set of nanosheets is wider than a width of the first set of nanosheets.

16. The semiconductor structure of claim 15, wherein the p-type transistor has source/drain regions formed at two ends of the first sub-set of the second set of nanosheets.

17. The semiconductor structure of claim 16, wherein two ends of the second sub-set of the second set of nanosheets are covered by a dielectric layer and isolated from the source/drain regions of the p-type transistor.

18. The semiconductor structure of claim 15, wherein the first set of nanosheets and the second set of nanosheets have a same number of nanosheets, and the first sub-set of the second set of nanosheets is positioned above the second sub-set of the second set of nanosheets.

19. The semiconductor structure of claim 15, wherein the first set of nanosheets and the second set of nanosheets are positioned in a same plane parallel to each other and separated by a dielectric layer.

20. The semiconductor structure of claim 15, wherein the p-type transistor is a pull-up transistor and the n-type transistor is either a pull-down transistor or a pass-gate transistor, and wherein the width of the first set of nanosheets is a channel width of the pull-down transistor or the pass-gate transistor and the width of the second set of nanosheets is a channel width of the pull-up transistor.
